(19) United States
(12) Patent Application Publication
(10) Pub. No.: US 2025/0194238 A1
(43) Pub. Date: Jun. 12, 2025

(54) STACKED FORKSHEET FET WITH SHARED AND/OR INDEPENDENT GATES

(71) Applicant: International Business Machines Corporation, Armonk, NY (US)

(72) Inventors: Shay Reboh, Guilderland, NY (US); Julien Frougier, Albany, NY (US); Ruilong Xie, Niskayuna, NY (US); Brent A. Anderson, Jericho, VT (US)

(21) Appl. No.: 18/537,365

(22) Filed: Dec. 12, 2023

(51) Int. Cl. H01L 27/092; H01L 21/8238; H01L 23/528; H01L 29/06; H01L 29/423; H01L 29/66; H01L 29/775; H01L 29/786

(52) U.S. Cl. CPC H10D 84/85; H01L 23/528; H10D 30/014; H10D 30/031; H10D 30/43; H10D 30/6735; H10D 30/6757; H10D 62/121; H10D 64/017; H10D 84/0186; H10D 84/038

(57) ABSTRACT

A semiconductor structure including a stacked forksheet FET is provided. The semiconductor structure includes a frontside gate cut structure that physically isolates a bottom forksheet FET from a top forksheet FET. The frontside gate cut structure provides a physical barrier that allows for a first metal gate electrode to be removed from the top forksheet FET without negatively impacting (i.e., removing) the first metal gate electrode of the bottom FET. After removal of the first metal gate electrode from the top forksheet FET, a second metal gate electrode can be formed in the area of the top forksheet FET which was previously occupied by the first metal gate electrode.

### BACKGROUND

The present application relates to semiconductor technology, and more particularly to a semiconductor structure including a stacked forksheet field effect transistor (FET).

A forksheet FET is a type of transistor that is being currently developed for 2 nm nodes and beyond. The stacked forksheet FET is an extension of vertically stacked nanosheets, where the nanosheets are controlled by a tri-gate forked structure, which is achieved by introducing a dielectric wall structure between the p-type FET (i.e., PFET) and n-type FET (i.e., NFET) devices. This isolation allows for tighter n-to-p spacing and higher performance. In forksheet devices, both the NFET and PFET are integrated in the same structure, unlike existing gate-all-around FETs that use different devices for the NFETs and PFETs. In a stacked forksheet FET configuration, one forksheet FET is stacked on top of another forksheet FET. Stacked forksheet FETs have improved circuit density and performance.

### SUMMARY

A semiconductor structure including a stacked forksheet FET is provided. The semiconductor structure includes a frontside gate cut structure that physically isolates a bottom forksheet FET from a top forksheet FET. The frontside gate cut structure provides a physical barrier that allows for a first metal gate electrode to be removed from the top forksheet FET without negatively impacting (i.e., removing) the first metal gate electrode of the bottom FET. After removal of the first metal gate electrode from the top forksheet FET, a second metal gate electrode can be formed in the area of the top forksheet FET which was previously occupied by the first metal gate electrode.

In one aspect of the present application, a semiconductor structure is provided. In one embodiment, the semiconductor structure includes a first forksheet transistor including a plurality of spaced apart and vertically stacked first semiconductor channel material nanosheets, and a first gate structure contacting each of the first semiconductor channel material nanosheets, wherein the first gate structure includes a first gate electrode and each first semiconductor channel material nanosheet has a first length. The structure further includes a second forksheet transistor located above the first forksheet transistor and including a plurality of spaced apart and vertically stacked second semiconductor channel material nanosheets, and a second gate structure contacting each of the second semiconductor channel material nanosheets, wherein the second gate structure includes a second gate electrode and each second semiconductor channel material nanosheet has a second length that is less than the first length. The structure even further includes a middle dielectric isolation layer separating a bottommost second semiconductor channel material nanosheet of the spaced apart and vertically stacked second semiconductor channel material nanosheets from a topmost first semiconductor channel material nanosheet of the spaced apart and vertically stacked first semiconductor channel material nanosheets. The structure yet further includes a frontside gate cut structure located adjacent to the second forksheet transistor and located over the middle dielectric isolation layer, wherein the frontside gate cut structure electrically isolates the first gate electrode from the second gate electrode.

### BRIEF DESCRIPTION OF THE DRAWINGS

FIG. 1 is a cross sectional view of an exemplary semiconductor structure that can be employed in the present application, the exemplary semiconductor structure including a substrate, a first nanosheet stack of alternating first sacrificial semiconductor material nanosheets and first semiconductor channel material nanosheets, a middle dielectric isolation layer, and a second nanosheet stack of alternating second sacrificial semiconductor material nanosheets and second semiconductor channel material nanosheets, wherein the first nanosheet stack and the middle dielectric isolation layer have a first length and the second nanosheet stack has a second length that is less than the first length, and wherein a sidewall of each of the first nanosheet stack, the middle dielectric isolation layer, and the second nanosheet stack is in direct physical contact with a sidewall of a dielectric wall structure.

FIG. 2 is a cross sectional view of the exemplary semiconductor structure shown in FIG. 1 after forming a sacrificial gate material.

FIG. 3 is a cross sectional view of the exemplary semiconductor structure shown in FIG. 2 after forming inner spacers, removing the sacrificial gate material, and suspending each first semiconductor channel material nanosheet of the first nanosheet stack and each second semiconductor channel material nanosheet of the second nanosheet stack.

FIG. 4 is a cross sectional view of the exemplary semiconductor structure shown in FIG. 3 after forming a first gate structure wrapping around and along a physically exposed sidewall of each first semiconductor channel material nanosheet of the first nanosheet stack, the middle dielectric isolation layer and each second semiconductor channel material nanosheet of the second nanosheet stack, the first gate structure including a first gate dielectric layer and a first gate electrode.

FIG. 5 is a cross sectional view of the exemplary semiconductor structure shown in FIG. 4 after forming a frontside gate cut structure.

FIG. 6 is a cross sectional view of the exemplary semiconductor structure shown in FIG. 5 after removing the first gate electrode that contacts each second semiconductor channel material nanosheet of the second nanosheet stack.

FIG. 7 is a cross sectional view of the exemplary semiconductor structure shown in FIG. 6 after forming a second gate electrode contacting each second semiconductor channel material nanosheet of the second nanosheet stack, and forming a frontside contact structure.

FIG. 8 is a cross sectional view of the exemplary semiconductor structure shown in FIG. 7 after forming a middle-of-the-line (MOL) dielectric layer and a frontside back-end-of-the-line (BEOL) interconnect structure, wherein the MOL dielectric layer includes MOL contact structures embedded therein.

FIG. 9 is a cross sectional view of the exemplary semiconductor structure shown in FIG. 8 after forming a carrier wafer on the frontside BEOL interconnect structure, and removing a first semiconductor layer of the substrate.

FIG. 10 is a cross sectional view of the exemplary semiconductor structure shown in FIG. 9 after removing an etch stop layer of the substrate, forming a backside gate cut structure and a backside interconnect structure.

FIG. 11 is a cross sectional view of another exemplary semiconductor structure in accordance with another embodiment of the present application.

FIG. 12 is a cross sectional view of a further exemplary semiconductor structure in accordance with a further embodiment of the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

Replacement metal gate (RMG) module in stacked nanosheet FET or stacked forksheet FET devices starts with the deposition of a gate dielectric material layer and a first replacement metal gate electrode corresponding to the replacement metal gate of the bottom FET. Dual replacement metal gates depend on the ability to remove the first replacement metal gate electrode from the top FET and replace it by a second metal gate electrode. In terms of process control, it is extremely difficult to remove the first replacement metal gate electrode from the top FET without also removing it from the bottom FET if there is no physical barrier for the chemistry used to remove the first replacement metal gate electrode.

In the present application, a solution to the RMG module problem mentioned above is provided by physically isolating the bottom FET from the top FET by forming a frontside gate cut structure in the region including the top FET. This frontside gate contact structure is located over the middle dielectric isolation layer and provides a physical barrier that allows for the first metal gate electrode to be removed from the top FET without negatively impacting (i.e., removing) the first metal gate electrode of the bottom FET. After removal of the first metal gate electrode from the top FET, a second metal gate electrode can be formed in the area that was previously occupied by the first metal gate electrode. The present application thus allows for the co-integration of an NFET metal gate electrode with a PFET metal gate electrode. Also, is also for design flexibility of merged on independent NFET and PFET gate contacts.

In the present application, a semiconductor structure is described and illustrated as containing a stacked forksheet transistor. A transistor (or FET)) includes a source region, a drain region, a semiconductor channel region located between the source region and the drain region, and a gate structure located above the semiconductor channel region. Collectively, the source region and the drain region can be referred to as a source/drain region. A forksheet FET is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. Each semiconductor channel material nanosheet has a sidewall that in in direct physical contact with a dielectric wall structure. The gate structure includes a gate dielectric and a gate electrode. The gate structure wraps contacts three surfaces (top and bottom and another sidewall) of each of the spaced apart semiconductor channel material nanosheets. In a stacked FET, one forksheet FET is stacked above another forksheet FET.

In the present application, the semiconductor structure includes a frontside and a backside. The frontside includes a side of the structure that includes the stacked forksheet FET, frontside contact structures, and a frontside BEOL structure. The backside of the semiconductor structure is the side of the device that is opposite the frontside. The backside includes a backside contact structure, and a backside interconnect structure.

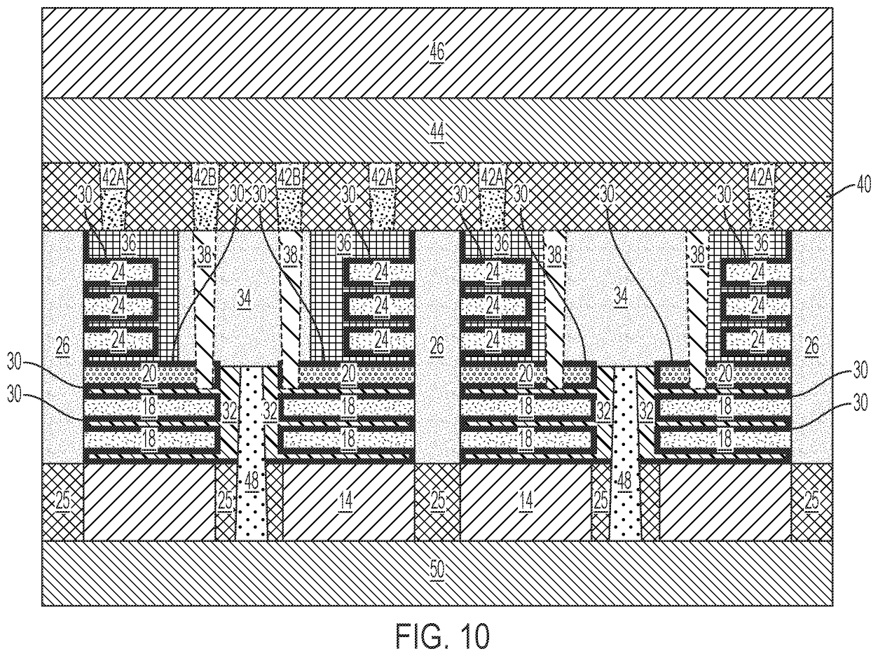

In one aspect of the present application (and as illustrated in FIGS. 10, 11 and 12), a semiconductor structure is provided. In one embodiment, the semiconductor structure includes a first (i.e., bottom) forksheet transistor including a plurality of spaced apart and vertically stacked first semiconductor channel material nanosheets 18, and a first gate structure contacting each of the first semiconductor channel material nanosheets 18, wherein the first gate structure includes a first gate electrode 32 and each first semiconductor channel material nanosheet 18 has a first length. The structure further includes a second (i.e., top) forksheet transistor located above the first forksheet transistor and including a plurality of spaced apart and vertically stacked second semiconductor channel material nanosheets 24, and a second gate structure contacting each of the second semiconductor channel material nanosheets 24, wherein the second gate structure includes a second gate electrode 36 and each second semiconductor channel material nanosheet 24 has a second length that is less than the first length. The structure even further includes a middle dielectric isolation layer 20 separating a bottommost second semiconductor channel material nanosheet of the spaced apart and vertically stacked second semiconductor channel material nanosheets from a topmost first semiconductor channel material nanosheet of the spaced apart and vertically stacked first semiconductor channel material nanosheets. The structure yet further includes a frontside gate cut structure 34 located adjacent to the second forksheet transistor and located over the middle dielectric isolation layer 20, wherein the frontside gate cut structure 34 electrically isolates the first gate electrode 32 from the second gate electrode 36.

In embodiments of the present application (See, FIGS. 10, 11 and 12), the structure can further include a dielectric wall structure 26 contacting a sidewall of each first semiconductor channel material nanosheet 18, the middle dielectric isolation layer 20, and each second semiconductor channel material nanosheet 24.

In some embodiments and as illustrated in FIG. 10 (left hand side), the structure can further include a frontside contact structure 38 passing through the frontside gate cut structure 34 and the middle dielectric isolation layer 20 and contacting the first gate electrode 32, wherein the frontside contact structure 38 is spaced apart from the second gate electrode 36 by a portion of the frontside gate cut structure 34. In such embodiments, a stacked forksheet FET including independent top and bottom gates are formed. In such independent top and bottom gates embodiments, the structure can further include a top gate MOL contact structure 42A contacting the second gate electrode 36, and a bottom gate MOL contact structure 42B contacting the frontside contact structure 38, wherein the top gate MOL contact structure 42A and the bottom gate MOL contact structure 42B are embedded in a MOL dielectric layer 40. In such independent top and bottom gates embodiments, the structure can further include a BEOL interconnect structure 44 contacting the MOL dielectric layer 40. In such independent top and bottom gates embodiments, the structure can further include a backside gate cut structure 48 located adjacent to the first gate electrode 32 and contacting the frontside gate cut structure 34.

In some embodiments and as illustrated in FIG. 10 (right hand side), the structure can further include a frontside contact structure 38 passing through the frontside gate cut structure 34 and the middle dielectric isolation layer 20 and contacting the first gate electrode 32, wherein the frontside contact structure 38 directly contacts a sidewall of the second gate electrode 36. In such embodiments, a stacked forksheet FET including shared top and bottom gates are formed. In such shared top and bottom gates embodiments, the structure can further include a top gate MOL contact structure 42A contacting the second gate electrode 36, wherein the top gate MOL contact structure 42A is embedded in a MOL dielectric layer 40. In such shared top and bottom gates embodiments, the structure can further include a frontside BEOL interconnect structure 44 contacting the MOL dielectric layer 40. In such shared top and bottom gates embodiments, the structure can further include a backside gate cut structure 48 located adjacent to the first gate electrode 32 and contacting the frontside gate cut structure 34. In such shared top and bottom gates embodiments, the backside gate cut structure can also contact a surface of a backside interconnect structure 50.

It is noted that the independent top and bottom gates and the shared top and bottom gates can be used separately on a single substrate or they can be combined on a single substrate as illustrated in FIG. 10.

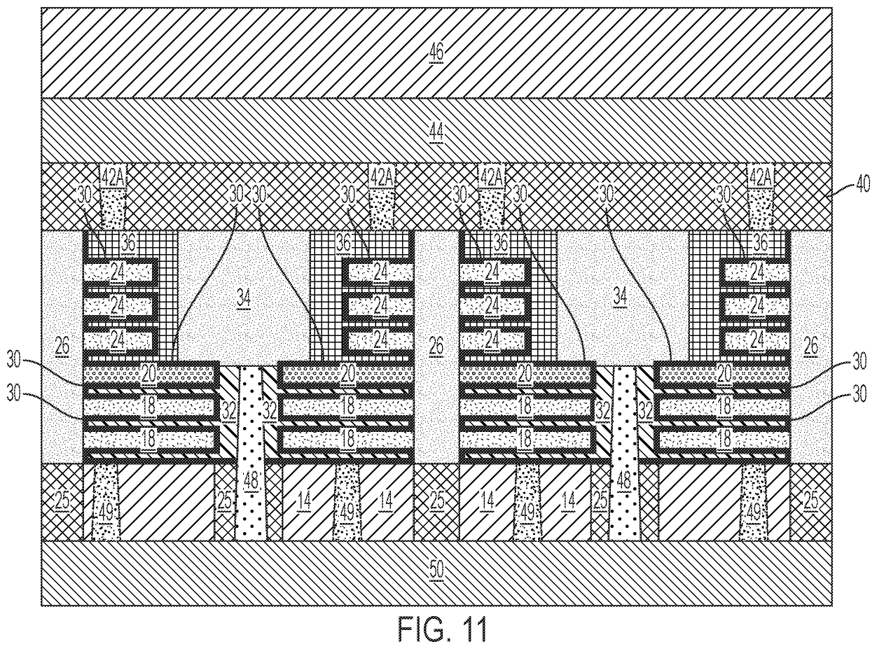

In some embodiments and as illustrated in FIG. 11, the structure can further include a top gate MOL contact structure 42A contacting the second gate electrode 36, and embedded in a MOL dielectric layer 40, and a backside contact structure 49 contacting the first gate structure. In such embodiments, the structure can further include a frontside BEOL interconnect structure 44 located on the MOL dielectric layer 40, and a backside interconnect structure 50 contacting the backside contact structure 49. In such embodiments, the structure can further include a backside gate cut structure 48 located adjacent to the first gate electrode 32 and contacting the frontside gate cut structure 34 and the backside interconnect structure 50. In some embodiments, frontside gate contact structure 38 can also be present on the frontside of the structure.

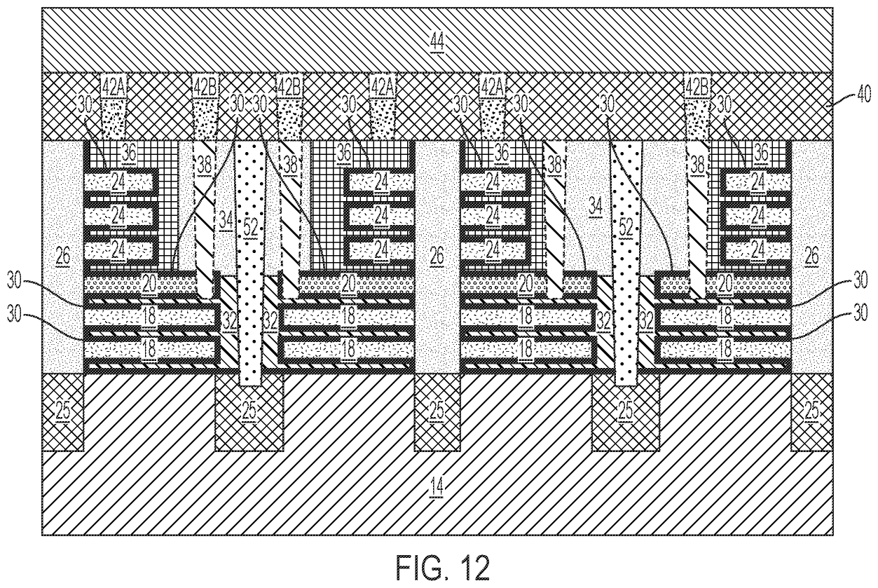

In some embodiments and as illustrated in FIG. 12, the structure can further include a frontside bottom gate cut structure 52 that passes through the frontside gate cut structure 34 and the first gate electrode 32. In such embodiments and as is shown on the left hand side of FIG. 12, the structure can further include a frontside contact structure 38 passing through the frontside gate cut structure 34 and the middle dielectric isolation layer 20 and contacting the first gate electrode 32, wherein the frontside contact structure 38 is spaced apart from the second gate electrode 36 by a portion of the frontside gate cut structure 34. In such independent top and bottom gates embodiments, the structure can further include a MOL top gate contact structure 42A contacting the second gate electrode 36 and embedded in a MOL dielectric layer 40, and a MOL bottom gate contact structure 42B contacting the frontside contact structure 38.

As is illustrated on the right hand side of FIG. 12, the structure that includes the frontside bottom gate cut structure 52 can further a frontside contact structure 38 passing through the frontside gate cut structure 34 and the middle dielectric isolation layer 20, and contacting the first gate electrode 32 and a sidewall of the second gate electrode 36. In such shared top and bottom gates embodiments, the structure can further include a MOL top gate contact structure 42A contacting the second gate electrode, or a MOL bottom gate structure 42B that contacts the frontside contact structure 38. It is noted that the independent top and bottom gates and the shared top and bottom gates can be used separately on a single substrate or they can be combined on a single substrate as illustrated in FIG. 12. It is noted that the MOL bottom gate structure 42B and the frontside contact structure 38 can be the same via.

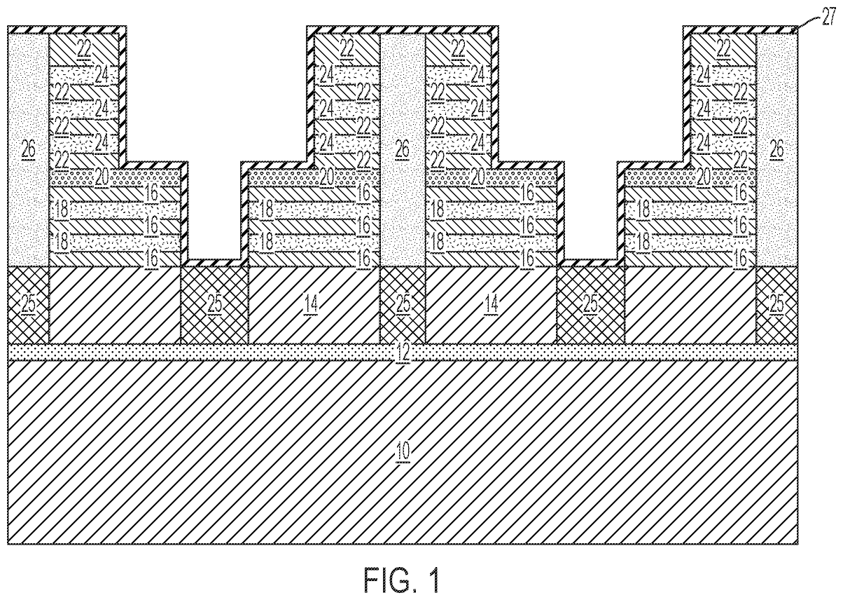

These and other aspects of the present application will now be described in greater detail by referring to FIGS. 1-12 that accompany this application.

Reference is first made to FIG. 1, which is a cross sectional view of an exemplary semiconductor structure that can be employed in the present application. The exemplary semiconductor structure includes a substrate, a first nanosheet stack of alternating first sacrificial semiconductor material nanosheets 16 and first semiconductor channel material nanosheets 18, a middle dielectric isolation layer 20, and a second nanosheet stack of alternating second sacrificial semiconductor material nanosheets 22 and second semiconductor channel material nanosheets 24. In the present application, the second nanosheet stack is located above the first nanosheet stack. Thus, the region including the first nanosheet stack is a first (or bottom) device region, and the region including the second nanosheet stack is a second (or top) device region. In the present application, a plurality of first nanosheet stacks, middle dielectric isolation layers 20, and second nanosheet stacks are shown.

As is illustrated in FIG. 1, the first nanosheet stack (including the first sacrificial semiconductor material nanosheets 16 and the first semiconductor channel material nanosheets 18) and the middle dielectric isolation layer 20 has a first length, and the second nanosheet stack (including the sacrificial semiconductor material nanosheets 22 and the second semiconductor channel material nanosheets 24) has a second length that is less than the first length. In the present application, a sidewall (i.e., hereinafter a first sidewall) of each of the first nanosheet stack (including the first sacrificial semiconductor material nanosheets 16 and the first semiconductor channel material nanosheets 18), the middle dielectric isolation layer 20 and the second nanosheet stack (including the sacrificial semiconductor material nanosheets 22 and the second semiconductor channel material nanosheets 24) is in direct physical contact with a sidewall of a dielectric wall structure 26.

In some embodiments of the present application and as is illustrated in FIG. 1, shallow trench isolation structures 25 can be present in the substrate. In other embodiments (not shown), the shallow trench isolation structures 25 can be omitted from the exemplary structure illustrated in FIG. 1. In embodiments in which the shallow trench isolation structures 25 is present, the dielectric wall structure 26 can land on a surface of one of the shallow trench isolation structures 25. The shallow trench isolation structure 25 can be used to define different active areas of the exemplary structure.

The illustrated semiconductor structure shown in FIG. 1 also includes a dielectric liner 27. Dielectric liner 27 is located on a sidewall (i.e., hereinafter a second sidewall) of each of the first nanosheet stack (including the first sacrificial semiconductor material nanosheets 16 and the first semiconductor channel material nanosheets 18), the middle dielectric isolation layer 20 and the second nanosheet stack (including the sacrificial semiconductor material nanosheets 22 and the second semiconductor channel material nanosheets 24) that is opposite the first sidewall mentioned above. Dielectric liner 27 is also present on a topmost surface of each of the second nanosheet stack, the dielectric wall structure 26, and, if present, at least one of the shallow trench isolation structures 25.

The various elements/components mentioned above and that are illustrated in FIG. 1 will now be described in greater detail. In the present application, the substrate can include a first semiconductor layer 10, an etch stop layer 12 and a second semiconductor layer 14. In embodiments, the first semiconductor layer 10 and/or the etch stop layer 12 can be omitted from the substrate. The first semiconductor layer 10 is composed of a first semiconductor material, and the second semiconductor layer 14 is composed of a second semiconductor material. The term “semiconductor material” is used throughout the present application to denote a material having semiconducting properties. Examples of semiconductor materials that can be used in the present application in providing the first semiconductor material and the second semiconductor material include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the second semiconductor layer 14 can be compositionally the same as, or compositionally different from, the first semiconductor material that provides the first semiconductor layer 10.

In some embodiments of the present application, the etch stop layer 12 can be composed of a dielectric material such as, for example, silicon dioxide and/or boron nitride. In other embodiments of the present application, the etch stop layer 12 is composed of a semiconductor material that is compositionally different from the first semiconductor material that provides the first semiconductor layer 10 and the second semiconductor material that provides the second semiconductor layer 14. In one example, the first semiconductor layer 10 is composed of silicon, the etch stop layer 12 is composed of silicon dioxide, and the second semiconductor layer 14 is composed of silicon. In another example, the first semiconductor layer 10 is composed of silicon, the etch stop layer 12 is composed of silicon germanium, and the second semiconductor layer 14 is composed of silicon.

The substrate including the first semiconductor layer 10, the etch stop layer 12 and the second semiconductor layer 14 can be formed utilizing techniques well known to those skilled in the art. For example, the substrate including the first semiconductor layer 10, the etch stop layer 12 and the second semiconductor layer 14 can be formed by a separation by ion implantation of oxygen process, or wafer bonding. Alternatively, the substrate including the first semiconductor layer 10, the etch stop layer 12 and the second semiconductor layer 14 can be formed by deposition of the various substrate layers one on top the other. The deposition used in forming the various substrate layers can include, but is not limited to, chemical vapor deposition (CVD), plasma enhanced chemical vapor deposition (PECVD), or epitaxial growth. The terms “epitaxial growth” or “epitaxially growing” means the growth of a semiconductor material on a growth surface of another semiconductor material, in which the semiconductor material being grown has the same crystalline characteristics as the growth surface of the another semiconductor material. In an epitaxial deposition process, the chemical reactants provided by the source gases are controlled and the system parameters are set so that the depositing atoms arrive at the growth surface of the another semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 450° C. to 900° C. Although higher temperature typically results in faster deposition, the faster deposition may result in crystal defects and film cracking.

As mentioned above, the first nanosheet stack includes alternating first sacrificial semiconductor material nanosheets 16 and first semiconductor channel material nanosheets 18. In some embodiments and as is illustrated in FIG. 1, the first nanosheet stack can include ‘n’ number of first semiconductor channel material nanosheets 18 and ‘n+1’ number of first sacrificial semiconductor material nanosheets 16, wherein n is an integer greater than one. By way of one example, the first nanosheet stack can include three first sacrificial semiconductor material nanosheets 16 and two first semiconductor channel material nanosheets 18. In the illustrated first nanosheet stack, each first semiconductor channel material nanosheet 18 is sandwiched between a bottom first sacrificial semiconductor material nanosheet and a top first sacrificial semiconductor material nanosheet. Each first sacrificial semiconductor material nanosheet 16 is composed of a third semiconductor material, while each first semiconductor channel material nanosheet 18 is composed of a fourth semiconductor material that is compositionally different from the third semiconductor material. In some embodiments, the fourth semiconductor material that provides each first semiconductor channel material nanosheet 18 can provide high channel mobility for NFET devices. In other embodiments, the fourth semiconductor material that provides each first semiconductor channel material nanosheet 18 can provide high channel mobility for PFET devices. The third semiconductor material that provides each first sacrificial semiconductor material nanosheet 16, and the fourth semiconductor material that provides each first semiconductor channel material nanosheet 18 can include one of the semiconductor materials mentioned above. In one example, the third semiconductor material that provides each first sacrificial semiconductor material nanosheet 16 is composed of a silicon germanium alloy having a germanium content from 20 atomic percent to 40 atomic percent and the fourth semiconductor material that provides each first semiconductor channel material nanosheet 18 is composed of silicon. Other combinations of semiconductor materials are possible as long as the third semiconductor material is compositionally different from the fourth semiconductor material.

As mentioned above, the second nanosheet stack includes alternating second sacrificial semiconductor material nanosheets 22 and second semiconductor channel material nanosheets 24. In some embodiments and as is illustrated in FIG. 1, the second nanosheet stack can include ‘m’ number of second semiconductor channel material nanosheets 24 and ‘m+1’ number of second sacrificial semiconductor material nanosheets 22, wherein m is an integer greater than one. Note that m can be equal to or different from n. By way of one example, the second nanosheet stack can include four second sacrificial semiconductor material nanosheets 22 and three second semiconductor channel material nanosheets 24. In the illustrated second nanosheet stack, each second semiconductor channel material nanosheet 24 is sandwiched between a bottom second sacrificial semiconductor material nanosheet and a top second sacrificial semiconductor material nanosheet. Each second sacrificial semiconductor material nanosheet 22 is composed of the third semiconductor material, while each second semiconductor channel material nanosheet 24 is composed of a fifth semiconductor material that is compositionally different from the third semiconductor material; the fifth semiconductor material can be compositionally the same as, or compositionally different than, the fourth semiconductor material. In some embodiments, the fifth semiconductor material that provides each second semiconductor channel material nanosheet 24 can provide high channel mobility for NFET devices. In other embodiments, the fifth semiconductor material that provides each second semiconductor channel material nanosheet 24 can provide high channel mobility for PFET devices. The third semiconductor material that provides each second sacrificial semiconductor material nanosheet 22, and the fifth semiconductor material that provides each second semiconductor channel material nanosheet 24 can include one of the semiconductor materials mentioned above. In one example, the third semiconductor material that provides each second sacrificial semiconductor material nanosheet 22 is composed of a silicon germanium alloy having a germanium content from 20 atomic percent to 40 atomic percent and the fifth semiconductor material that provides each second semiconductor channel material nanosheet 22 is composed of silicon or germanium. Other combinations of semiconductor materials are possible as long as the third semiconductor material is compositionally different from the fifth semiconductor material.

The middle dielectric isolation layer 20 is composed of a dielectric material such as for example, silicon dioxide, SiN, SiBCN, SiOCN or SiOC. In the present application, the middle dielectric isolation layer 20 is sandwiched between the first nanosheet stack and the second nanosheet stack. The middle dielectric isolation layer 20 provides a horizontal boundary between the first (bottom) device region and the second (top) device region.

Each shallow trench isolation structure 25 is composed of a trench dielectric material such as, for example, silicon oxide. In some embodiments, a trench dielectric liner composed of, for example, SiN, can be present along a sidewall and a bottom wall of the trench dielectric material. The shallow trench isolation structure 25 has a topmost surface that is substantially coplanar with, or slightly below, a topmost surface of the second semiconductor layer 14. The height of each shallow trench isolation structure 25 can be the same or different. For example, the height of the shallow trench isolation structure 25 that is located beneath the middle dielectric wall structure shown in FIG. 1 can be different from the height of the other shallow trench isolation structures 25 that flank that middle dielectric wall structure.

Each dielectric wall structure 26 is composed of one or more dielectric materials. The dielectric material(s) that provide the dielectric wall structure 26 is typically compositionally different from at least the dielectric material that provides the middle dielectric isolation layer 20. The dielectric material(s) that provide(s) the dielectric wall structure 26 can be composed of silicon oxide, a silicon carbon based dielectric material such as, for example, silicon carbide or a dielectric including atoms of Si, C and O, or any combination of the same. Other dielectric materials besides the ones listed can be employed in the present application in providing the dielectric wall structure 26.

The dielectric liner 27 is composed of a dielectric material that is typically compositionally different from at least the dielectric material that provides the dielectric wall structure 26 and/or the middle dielectric isolation layer 20. The dielectric liner 27 can be composed of, for example, silicon oxide, silicon nitride or SiBCN. The dielectric liner 27 is typically a conformal layer having a thickness typically from 2 nm to 5 nm. The term ‘conformal” denotes that a layer has a same thickness as measured from a horizontal surface of another layer as a thickness as measured from a vertical surface of the another layer.

The exemplary semiconductor structure illustrated in FIG. 1 can be formed utilizing well known processing steps. Notably, a first wafer including the second semiconductor layer 14 and a non-patterned first material stack of blanket layers of alternating third semiconductor material and fourth semiconductor material is provided. The blanket layers of alternating third semiconductor material and fourth semiconductor material can be formed by, for example, CVD, PECVD, epitaxial growth or any combination of such deposition processes. In some embodiments, the first wafer also includes a blanket layer of the dielectric material that provides a portion of, or an entirety of, the middle dielectric isolation layer 20 is deposited on the non-patterned first nanosheet stack. The deposition of the blanket layer of dielectric material can include CVD, PECVD, or physical vapor deposition (PVD). A second wafer including a handler substrate and a non-patterned second material stack of blanket layers of alternating third semiconductor material and fifth semiconductor material is also provided. The blanket layers of alternating third semiconductor material and fifth semiconductor material can be formed by, for example, CVD, PECVD, epitaxial growth or any combination of such deposition processes. In some embodiments, the second wafer also includes a blanket layer of the dielectric material that provides a portion of, or an entirety of, the middle dielectric isolation layer 20 is deposited on the non-patterned second nanosheet stack. The first and second wafers are then bonded together such that the blanket layer of the dielectric material is located between the first and second non-patterned material stacks. The handler wafer is removed after wafer bonding. In some embodiments, a sacrificial etch stop layer can be present on the handler wafer prior to forming the non-patterned second material stack. This sacrificial etch stop layer is removed after wafer bonding. Removal of the handler wafer and the sacrificial etch stop layer can be performed utilizing one or more material removal processes. In on example, the handler substrate is removed by planarization (chemical mechanical polishing (CMP) or grinding), and the sacrificial etch stop layer can be removed utilizing an etching process.

A first nanosheet patterning process can be performed on the non-patterned second material stack, the blanket layer of dielectric material, and the non-patterned first material stack. The first nanosheet patterning process includes lithography and etching. Lithography includes forming a photoresist material on a layer or stack of material layers that need to be patterned, exposing the photoresist material to a desired pattern of irradiation, and thereafter developing the exposed photoresist material utilizing a conventional resist developer. The developed photoresist material has a desired pattern (i.e., nanosheet pattern) that is then transferred to the layer or stack of material layers that need to be patterned by etching. Etching can include dry etching and/or chemical wet etching. In one embodiment, a dry etch such as, for example, reactive ion etching (RIE), ion beam etching (IBE), plasma etching or any combination thereof can be used to transfer the pattern to the layer or stack of material layers that need to be patterned. The first nanosheet patterning process converts the blanket layer of dielectric material into the middle dielectric isolation layer 20, and the non-patterned first material stack into the first nanosheet stack mentioned above. The first nanosheet patterning process provides the first length to both the middle dielectric isolation layer 20 and the first nanosheet stack. The first nanosheet patterning process also converts the non-patterned second material stack into a precursor second nanosheet stack. The precursor second nanosheet stack has the first length mentioned above. A second nanosheet patterning process can then be performed to reduce the length of the precursor second nanosheet stack to provide the second nanosheet stack having the second length mentioned above. Each of the twice nanosheet patterned structures includes the first nanosheet stack, the middle dielectric isolation layer 20 and the second nanosheet stack mentioned above.

Next, the shallow trench isolation structures 25 can be formed by etching a trench into the second semiconductor layer 14, depositing the optional trench dielectric liner material and the trench dielectric material in the trench, and thereafter performing an etch back process.

Dielectric wall structure 26 can thereafter by formed by deposition of a dielectric layer such that the dielectric layer merges or pinches off in the small gap that is located between each first and second nanosheet stacks. An isotropic removal process is then performed to remove the dielectric layer in areas in which pinch off did not occur.

Dielectric liner 27 is then formed by utilizing a conformal deposition process such as, for example, CVD, PECVD or ALD.

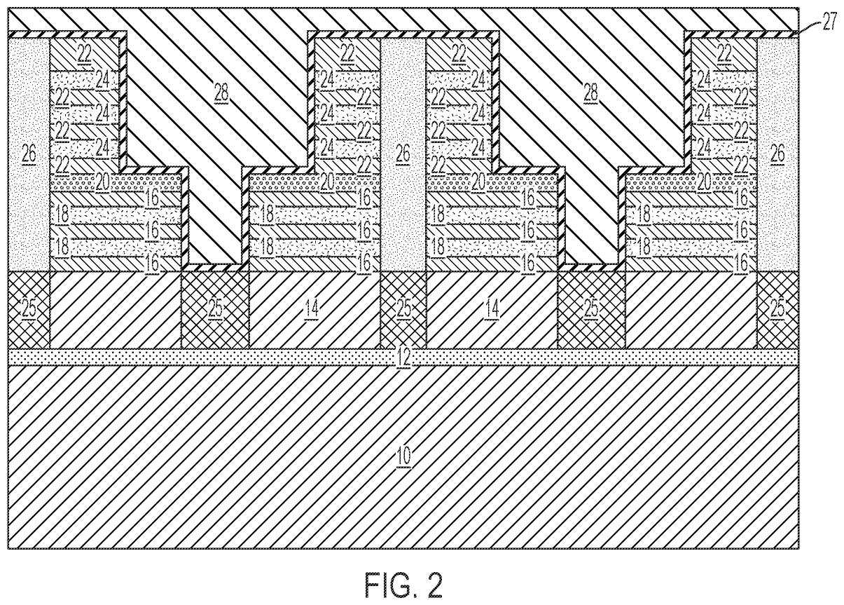

Referring now to FIG. 2, there is illustrated the exemplary semiconductor structure shown in FIG. 1 after forming a sacrificial gate material 28. The sacrificial gate material 28 can be composed of, for example, polysilicon, amorphous silicon, amorphous silicon germanium or amorphous germanium. The sacrificial gate material 28 can be formed by a deposition process such as, for example, CVD, PECVD, PVD or ALD. The sacrificial gate material 28 is formed on the dielectric liner 27 and where multiple twice nanosheet patterned structures are formed it is formed in the gap that is located between each neighboring pair of twice nanosheet patterned structures. The sacrificial gate material 28 has a topmost surface that extends above the topmost surface of the second nanosheet stack of each twice nanosheet patterned structure.

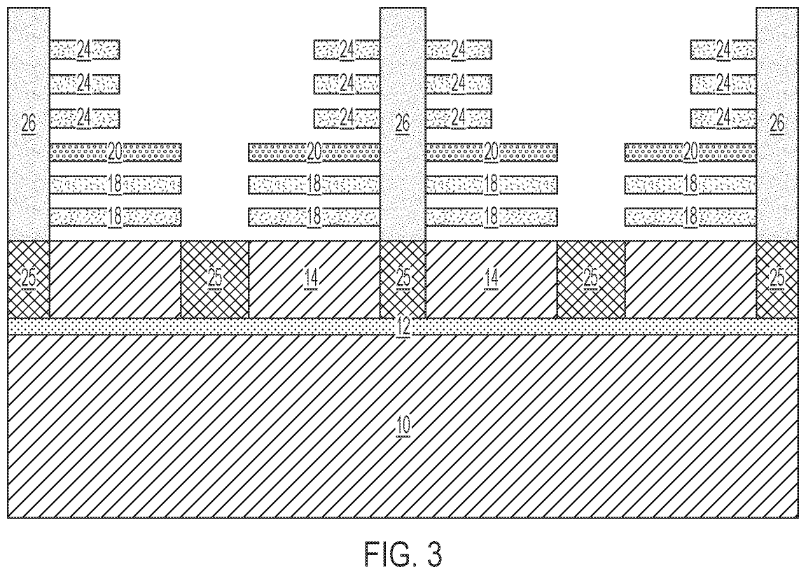

Referring now to FIG. 3, there is illustrated the exemplary semiconductor structure shown in FIG. 2 after forming inner spacers (not shown), removing the sacrificial gate material 28, and suspending each first semiconductor channel material nanosheet 18 of the first nanosheet stack and each second semiconductor channel material nanosheet 24 of the second nanosheet stack.

The inner spacers are not shown in the cross view provided. Instead, the inner spacers would be formed into and out of the plane of the drawings sheet containing FIG. 3. The inner spacers are formed by first recessing, i.e., indenting, each of the first sacrificial semiconductor material nanosheets 16 and each of the second sacrificial semiconductor material nanosheets 22. After the recessing step, a gap is formed at the ends of each of the first sacrificial semiconductor material nanosheets 16 and each of the second sacrificial semiconductor material nanosheets 22. The recessing includes a lateral etching process that removes end portions of each first sacrificial semiconductor material nanosheets 16 and each of the second sacrificial semiconductor material nanosheets 22. This lateral etch does not indent the first semiconductor channel material nanosheets 18 or the second semiconductor channel material nanosheets 24. Next, a layer of an inner spacer dielectric material is formed by a deposition process such as, for example, CVD, PECVD or ALD. This layer of inner spacer dielectric material fills in each of the gaps and is formed along a sidewall of each first semiconductor channel material nanosheet 18, the middle dielectric isolation layer 20 and each second semiconductor channel material nanosheet 24. During the deposition of the inner spacer dielectric material, the inner spacer dielectric material pinches in the gaps created above. The inner spacer dielectric material can include, but is not limited to, silicon dioxide, SiN, SiBCN, SiOCN or SiOC. After depositing the layer of inner spacer dielectric material, an isotropic etch back process is performed on the layer of spacer dielectric material. The isotropic etch back process removes the layer of inner spacer dielectric material that is present on the sidewalls of the each first semiconductor channel material nanosheet 18, the middle dielectric isolation layer 20 and each second semiconductor channel material nanosheet 24, while maintaining the layer of inner spacer dielectric material in each gaps. The maintained layer of inner spacer dielectric material within each of the gaps provides the inner spacers.

Although not shown, bottom source/drain regions and top source/drain regions can be formed after inner spacer formation utilizing techniques well known to those skilled in the art. The bottom source/drain regions and the top source/drain regions would run into and out of the plane of the drawing sheet including FIG. 3. The bottom source/drain regions and the top source/drain regions are typically formed by an epitaxial growth process. As used herein, a “source/drain” region can be a source region or a drain region depending on subsequent wiring and application of voltages during operation of the FET. In the present application, the bottom source/drain regions are formed first, followed by forming a source/drain separating dielectric layer, and thereafter the second source/drain regions are formed. The bottom and top source/drain regions comprise a semiconductor material and a dopant. The semiconductor material that provides each source/drain region can include one of the semiconductor materials mentioned above for the first semiconductor layer 10. The semiconductor material that provides the source/drain regions can be compositionally the same, or compositionally different from each semiconductor channel material nanosheet that is present in the respective device region, i.e., top device region and bottom device region. The dopant that is present in each source/drain region can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each source/drain region can have a dopant concentration of from 4×10²⁰ atoms/cm³ to 3×10²¹ atoms/cm³. In one example, each bottom source/drain region is composed of phosphorus doped silicon.

After inner spacer and source/drain formation, the sacrificial gate material 28 and the dielectric liner 27 are removed to reveal each twice nanosheet patterned structure. The sacrificial gate material 28 and the dielectric liner 27 can be removed utilizing at least one material removal process such as, for example, etching, that is selective in removing the sacrificial gate material 28 and the dielectric liner 27. In some embodiments, a first etch is used to remove the sacrificial gate material and a second etch is used to remove the dielectric liner 27.

After sacrificial gate material 28 and dielectric liner 27 removal, each first sacrificial semiconductor material nanosheet 16 and each second sacrificial semiconductor material nanosheet 22 are removed to suspend each first semiconductor channel material nanosheet 18, the middle dielectric isolation layer 20, and each second semiconductor channel material nanosheet 24 as is shown in FIG. 3. The suspended first semiconductor channel material nanosheets 18, the suspended middle dielectric isolation layer 20, and the suspended second semiconductor channel material nanosheet 24 are anchored in place by the dielectric wall structure 26 and the inner spacers (not shown). The removal of each first sacrificial semiconductor material nanosheet 16 and each second sacrificial semiconductor material nanosheet 22 is performed utilizing any material removal process such as, for example, etching, which is selective in removing the third semiconductor material that was used in providing the first sacrificial semiconductor material nanosheets 16 and the second sacrificial semiconductor material nanosheets 22. This removal process does not remove each first semiconductor channel material nanosheet 18, the middle dielectric isolation layer 20, and each second semiconductor channel material nanosheet 24.

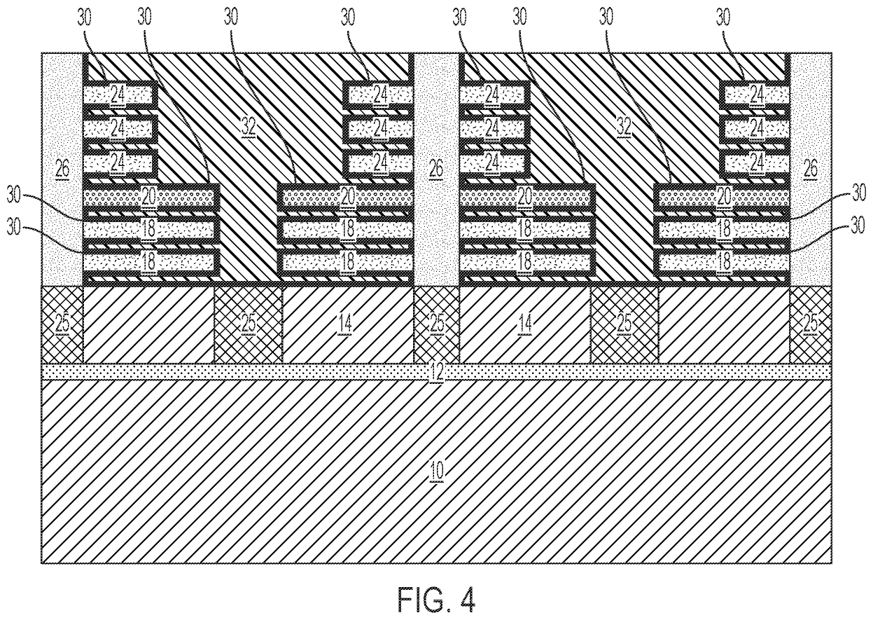

Referring now to FIG. 4, there is illustrated the exemplary semiconductor structure shown in FIG. 3 after forming a first gate structure wrapping around and along a physically exposed sidewall of each first semiconductor channel material nanosheet 18 of the first nanosheet stack, the middle dielectric isolation layer 20, and each second semiconductor channel material nanosheet 24 of the second nanosheet stack, the first gate structure including a first gate dielectric layer 30 and a first gate electrode 32.

In the present application, the first gate dielectric layer 30 is formed directly on physically exposed surfaces of each first semiconductor channel material nanosheet 18, the middle dielectric isolation layer 20, and each second semiconductor channel material nanosheet 24. The first gate electrode 32 is formed on the first gate dielectric layer 30. The first gate dielectric layer 30 is composed of a first gate dielectric material that has a dielectric constant of greater than 3.9; all dielectric constants mentioned in this application are measured in a vacuum unless otherwise stated. Illustrative examples of first gate dielectric materials that can be used in providing the first gate dielectric layer 30 include, but are not limited to, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The first gate dielectric material that provides the first gate dielectric layer 30 can further include dopants such as lanthanum (La), aluminum (Al) and/or magnesium (Mg).

The first gate electrode 32 is composed of a first gate electrode material. The first gate electrode material can include a first work function metal (WFM) and optionally a first conductive metal. The first WFM can be used to set a threshold voltage of the transistor to a desired value. In some embodiments, the first WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the first WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional first conductive metal can include, but is not limited to aluminum (Al), tungsten (W), or cobalt (Co). The first gate structure including the first gate dielectric layer 30 and the first gate electrode 32 can be formed by deposition of the first gate dielectric material and the first gate electrode material, followed by a planarization process which removes any first gate dielectric material and first gate electrode material that is formed on top of the dielectric wall structures 26.

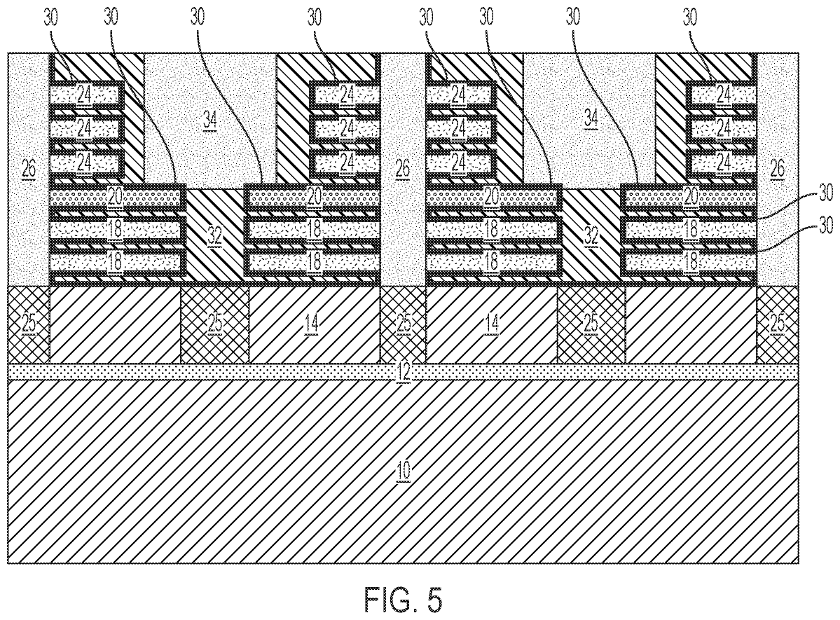

Referring now to FIG. 5, there is illustrated the exemplary semiconductor structure shown in FIG. 4 after forming a frontside gate cut structure 34. The frontside gate cut structure 34 is formed in the top device region. The frontside gate cut structure 34 contacts the first gate dielectric layer 30 that is present on the middle dielectric isolation layers 20. In some embodiments, the first gate dielectric layer 30 can be etched during the formation of the frontside gate cut structure 34. In the illustrated embodiment, the frontside gate cut structure 34 spans over a neighboring pair of middle dielectric isolation layer 20. The frontside gate cut structure 34 electrically separates the top device region from the bottom device region. The frontside gate cut structure 34 has a topmost surface that is substantially coplanar to at least a topmost surface of the dielectric wall structures 26.

The frontside gate cut structure 34 is formed by a gate cut process. The gate cut process includes forming a gate cut masking layer (not shown) over the exemplary structure shown in FIG. 4. The gate cut masking layer has at least one opening that corresponds to a region in which a gate cut trench is to be subsequently formed. With the gate cut masking layer in place, an etch is used to remove a physically exposed portion of the first gate electrode 32 in the top device region. After forming the gate cut trench, the gate cut trench is filled with a gate cut dielectric material such as, for example silicon nitride, silicon oxide, or a combination thereof. The gate cut dielectric material can be formed utilizing a deposition process such as, for example, ALD, CVD or PECVD. A planarization process such as, for example, CMP can follow the deposition of the gate cut dielectric material. The gate cut dielectric material that remains in the gate cut trench provides the frontside gate cut structure 34. It is noted that the gate cut masking layer can be removed after this etch and prior to filling the gate cut trench utilizing another etching process, or it can be removed after filling process by the planarization step mentioned above.

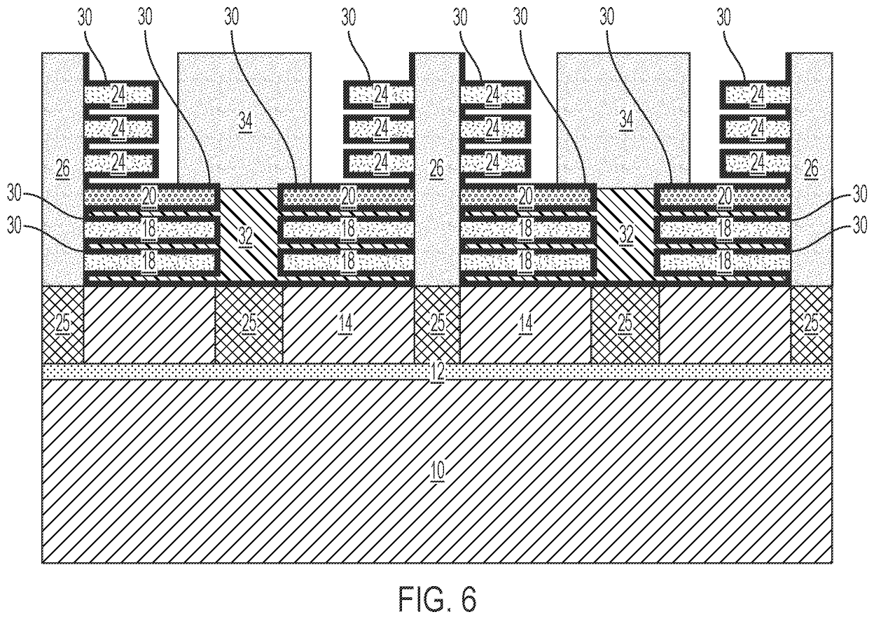

Referring now to FIG. 6, there is illustrated the exemplary semiconductor structure shown in FIG. 5 after removing the first gate electrode 32 that is in contact with each second semiconductor channel material nanosheet 24 of the second nanosheet stack, In some embodiments (not shown), the first gate dielectric layer 30 can also be removed from each second semiconductor channel material nanosheet 24 of the second nanosheet stack and from a topmost surface of the middle dielectric isolation layer 20 that is not covered by the frontside gate cut structure 34. The removal of the first gate dielectric layer 30 from the top device region is not preferred since it can raise the thermal budget of the processing flow. The removal of the first gate electrode 32 from the top device region can be performed utilizing a material removal process such as, for example, an etch, that is selective in removing the first gate electrode material. When the first gate dielectric layer 30 is removed from the top device region another material removal process such as, for example, an etch, that is selective in removing the first gate dielectric material.

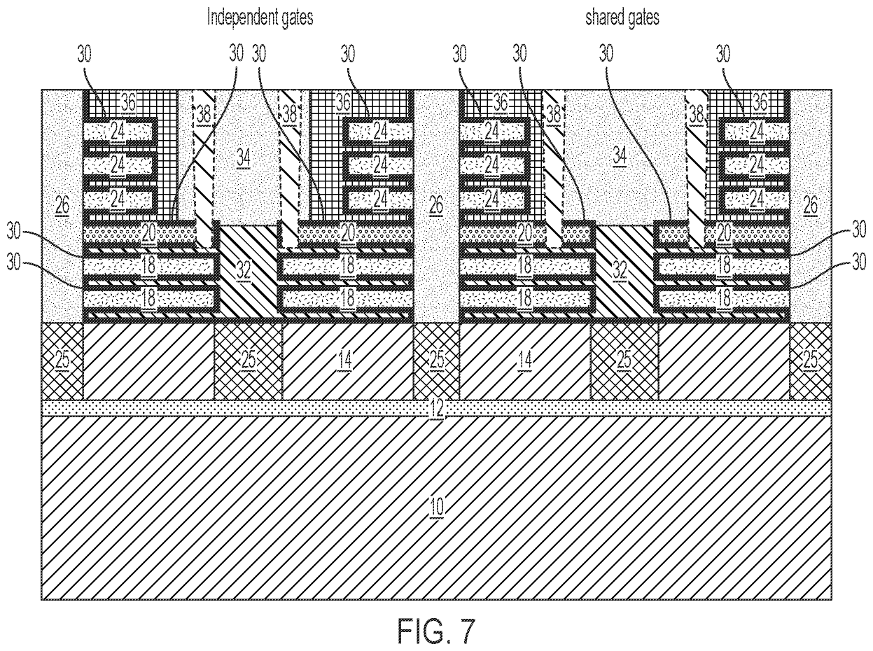

Referring now to FIG. 7, there is illustrated the exemplary semiconductor structure shown in FIG. 6 after forming a second gate electrode 36 contacting each second semiconductor channel material nanosheet 24 of the second nanosheet stack, and forming a frontside contact structure 38. In embodiments in which the first gate dielectric layer 30 is removed from the top device region, a second gate dielectric layer (not shown) can be formed on the physically exposed surfaces of each second semiconductor channel material nanosheet 24 and the middle dielectric isolation layer 20. In such embodiments, the second gate dielectric layer includes a second gate dielectric material that is typically, but not necessarily always, compositionally different from the first gate dielectric material. The second gate dielectric material can be selected from one of the first gate dielectric materials mentioned above. The second gate dielectric material can be formed by a deposition process such as, for example, CVD, PECVD or ALD.

The second gate electrode 36 is composed of a second gate electrode material which is typically compositionally different from the first gate electrode material. In embodiments, the second gate electrode material can include a second work function metal (WFM) and optionally a second conductive metal. The second WFM can be used to set a threshold voltage of the transistor to a desired value and can include one of the WFM materials mentioned above for the first WFM. The optional second conductive metal can include, but is not limited to aluminum (Al), tungsten (W), or cobalt (Co). The second gate electrode 36 can be formed by a deposition process such as, for example, CVD, PECVD or ALD.

In some embodiments, the first gate electrode 32 present in the bottom device region is composed of an n-type work function metal, while the second gate electrode 36 present in the top device region is composed of an n-type work function metal that is compositionally different from the n-type work function metal present in the bottom device region. In yet other embodiments, the first gate electrode 32 and the second gate electrode 36 are composed of a same n-type or p-type workfunction metal.

In some embodiments, the first gate electrode 32 present in the bottom device region is composed of a p-type work function metal, while the second gate electrode 36 present in the top device region is composed of a p-type work function metal that is compositionally different from the p-type work function metal present in the bottom device region. As previously mentioned, the first gate electrode 32 and the second gate electrode 36 can also be composed of a same n-type or p-type workfunction metal.

In some embodiments, the first gate electrode 32 present in the bottom device region is composed of an n-type work function metal, while the second gate electrode 36 present in the top device region is composed of a p-type work function metal.

In some embodiments, the first gate electrode 32 present in the bottom device region is composed of a p-type work function metal, while the second gate electrode 36 present in the top device region is composed of an n-type work function metal.

Thus, and in the present application, the structure that is formed can include a NFET stacked over another NFET, a PFET stacked over another PFET, a NFET stacked over a PFET or a PFET stacked over an NFET. In embodiments, the top device region and/or the bottom device region can have mixed NFETs and PFETs.

After performing the above replacement gate process in the top device region, a frontside contact structure 38 is formed. The frontside contact structure 38 is formed entirely through the frontside gate cut structure 34 and the middle dielectric isolation layer 20, and partially through the first gate electrode 32. The frontside contact structure 38 is thus formed in direct contact with the first gate electrode 32. In some embodiments, and as is illustrated on the left hand side of FIG. 7, the frontside contact structure 38 is spaced apart from the second gate electrode 36 by a portion of the frontside gate cut structure 34. In such embodiments, independent gates (top and bottom) are formed. In other embodiments, and as is illustrated on the right hand side of FIG. 7, the frontside contact structure 38 directly contacts a sidewall of the second gate electrode 36. In such embodiments, shared gates (top and bottom) are formed. Note that the present application can form both types of frontside contact structure 38 as is shown in FIG. 7.

In either embodiment, the frontside contact structure 38 can be formed by first forming a frontside contact structure trench into the frontside gate cut structure 34, the middle dielectric isolation layer 20, and the first gate electrode 32. The frontside contact structure trench can be formed by lithography and etching. The frontside contact structure trench is then filled (including deposition and planarization) with at least a contact conductor material. The contact conductor material that can be used for providing the frontside contact structure 38 includes, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. The frontside contact structure 38 can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above.

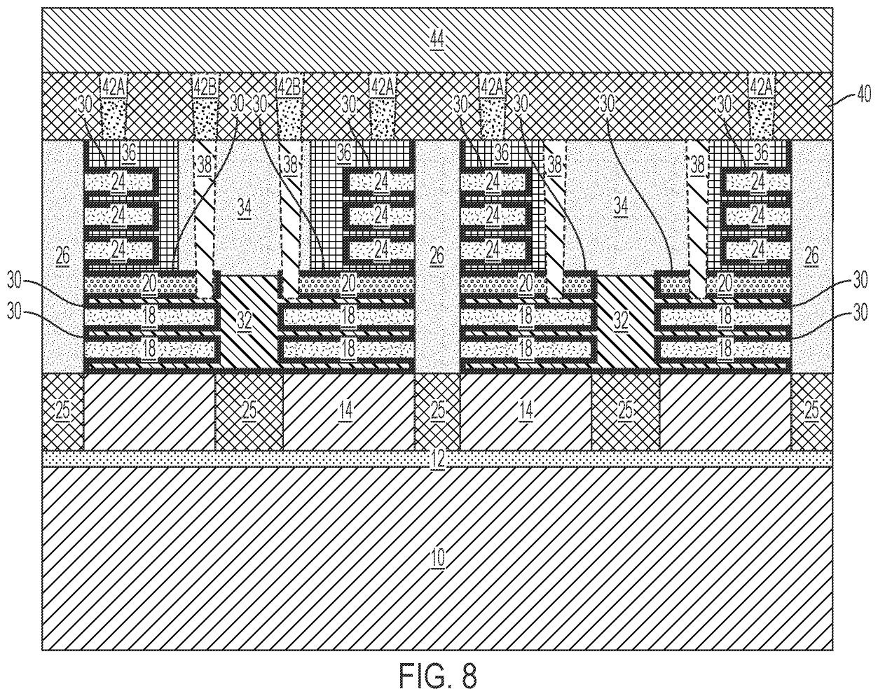

Referring now to FIG. 8, there is illustrated the exemplary semiconductor structure shown in FIG. 7 after forming a MOL dielectric layer 40 and a frontside BEOL interconnect structure 44, wherein the MOL dielectric layer 40 includes MOL contact structures embedded therein. The MOL dielectric layer 40 is composed of a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer, or any combination thereof. The term “low-k” as used throughout the present application denotes a dielectric material that has a dielectric constant of less than 4.0 The MOL dielectric layer 40 can be formed by a deposition process including, but not limited to, CVD, PECVD or spin-on coating. A planarization process such as, for example, CMP follows the deposition process.

A metallization process is then used to form MOL contact structures in the MOL dielectric layer 40. The metallization process includes the processing steps mentioned above in forming the frontside contact structure 38. MOL contact structures also includes materials mentioned above for forming the frontside contact structure 38. In some embodiments in which independent gates (top and bottom) are formed, the MOL contact structures can include a top gate MOL contact structure 42A and a bottom gate MOL contact structure 42B which is connected to the bottom gate via the frontside contact structure 38. This embodiment is shown on the left hand side of FIG. 8. In other embodiments in which shared gates (top and bottom) are formed, only a top gate MOL contact structure 42A is needed since the first gate electrode 32 and the second gate electrode 36 are both connected by the frontside contact structure 38. This embodiment is shown on the right hand side of FIG. 8. The MOL contact structures typically have a topmost surface that is substantially coplanar with a topmost surface of the MOL dielectric layer 40. In some embodiments (not illustrated), top gate MOL contact structure 42A could also contact the frontside contact structure 38 on the right hand side of the drawing.

Next, BEOL interconnect structure 44 is formed on the MOL dielectric layer 40 utilizing techniques well known to those skilled in the art. For example, the BEOL interconnect structure 44 can be formed utilizing a single damascene or a dual damascene process. The BEOL interconnect structure 44 includes at least one interconnect level that includes electrically conductive structures (not separately shown), such as, for example, Cu structures, embedded in an interconnect dielectric material layer (not separately shown), such as, for example, one of the dielectric materials mentioned above for the MOL dielectric layer 40.

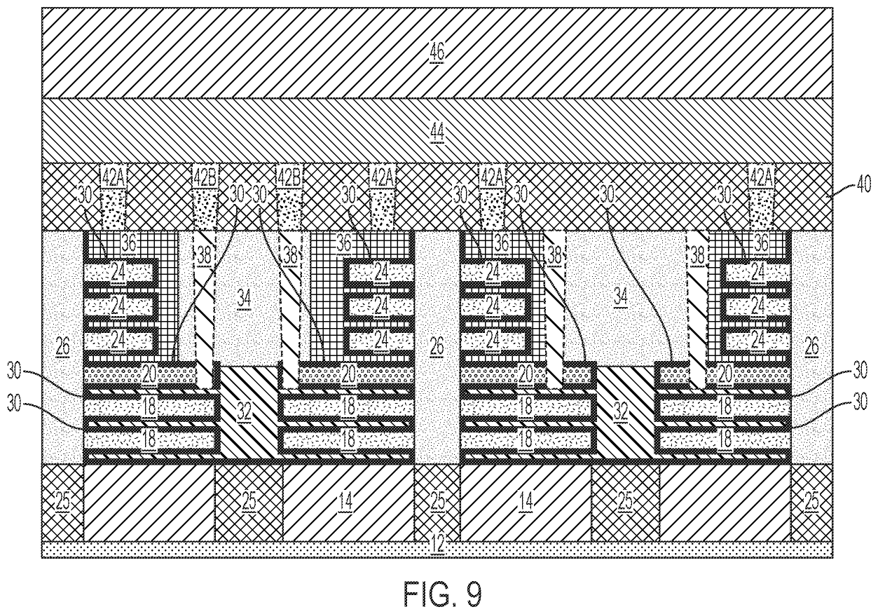

Referring now to FIG. 9, there is illustrated the exemplary semiconductor structure shown in FIG. 8 after forming a carrier wafer 46 on the frontside BEOL interconnect structure 44, and removing a first semiconductor layer 10 of the semiconductor substrate. Carrier wafer 46 is formed on the BEOL interconnect structure 44 utilizing techniques, such as, for example, wafer bonding, which are well known to those skilled in the art. The carrier wafer 46 can include one of the semiconductor materials mentioned above for the first semiconductor layer 10. The use of the carrier wafer 46 permits backside processing of the exemplary structure.

This backside processing includes flipping the structure 180°, and then removing the first semiconductor layer 10 if that layer is present. This flipping step is not shown in FIG. 8 for clarity. The flipping of the structure can be performed manually or utilizing a robot arm. This flipping revels a backside surface of first semiconductor layer 10 if the same is present. The reveled first semiconductor layer 10 is then removed utilizing an etching process that is selective in removing the first semiconductor layer 10. The etching process stops on the etch stop layer 12 if the same is present.

Referring now to FIG. 10, there is illustrated the exemplary semiconductor structure shown in FIG. 9 after removing an etch stop layer 12 of the substrate, forming a backside gate cut structure 48 and a backside interconnect structure 50. Etch stop layer 12 is removed utilizing an etching process that is selective in removing the etch semiconductor layer 12. The etching process stops on the second semiconductor layer 14. Backside gate cut structure 48 cuts the first gate electrode 32 as shown in FIG. 9. The backside gate cut structure 48 can be formed utilizing the process technique mentioned above in forming the frontside gate cut structure 34. The backside gate cut structure 48 can include one of the dielectrics mentioned above for the frontside gate cut structure 34. In the present application, the backside gate cut structure 48 passes through one of the shallow trench isolation structures 25 (if the same is present), the first gate dielectric layer 30 that is present on a surface of the second semiconductor layer 14, and the first gate electrode 32, and the backside gate cut structure 48 contacts a bottom surface of the frontside gate cut structure 34.

Backside interconnect structure 50 is formed on a physically exposed surface of the second semiconductor layer 14. The backside interconnect structure 50 can be formed utilizing the materials and techniques mentioned above in forming the frontside BEOL interconnect structure 44.

Referring now to FIG. 11, there is illustrated another exemplary semiconductor structure in accordance with the present application. This exemplary structure includes all element shown in FIG. 10 except for the frontside contact structure 38. In this exemplary structure, a backside contact structure 49 is present that contacts both the backside interconnect structure 50 and the first gate structure that is present in the bottom device region. The backside contact structure 49 is formed through the second semiconductor layer 14 and it can be formed utilizing the technique mentioned above in forming the frontside contact structure 38. The backside contact structure 49 includes materials as mentioned above for the frontside contact structure 38.

Referring now to FIG. 12, there is illustrated a further exemplary semiconductor structure in accordance with a further embodiment of the present application. This exemplary structure shown in FIG. 12 is substantially identical to that shown in FIG. 10 except that no backside processing was performed, and in this embodiment frontside bottom gate cut structure 52 is present; in such an embodiment the frontside gate cut structure 34 can be referred to a frontside top gate cut structure. In this embodiment, the starting substrate includes only the second semiconductor layer 14. In this embodiment, the frontside bottom gate cut structure 52 passes through the frontside gate cut structure 34 and the first gate electrode 32 and contacts a surface of the shallow trench isolation structure 25. The frontside bottom gate cut structure 52 can be formed utilizing materials and the processing technique mentioned above for forming frontside gate cut structure 34. In the independent top and bottom gates embodiments (left hand side of FIG. 12), the MOL top gate contact structure 42A and the MOL bottom contact structure 42B are both present, In the shared top and bottom gates embodiments (right hand side of FIG. 12), the MOL top gate contact structure 42A or the MOL bottom contact structure 42B is present in a single stacked forksheet FET.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a first forksheet transistor comprising a plurality of spaced apart and vertically stacked first semiconductor channel material nanosheets, and a first gate structure contacting each of the first semiconductor channel material nanosheets, wherein the first gate structure comprises a first gate electrode and each first semiconductor channel material nanosheet has a first length;
a second forksheet transistor located above the first forksheet transistor and comprising a plurality of spaced apart and vertically stacked second semiconductor channel material nanosheets, and a second gate structure contacting each of the second semiconductor channel material nanosheets, wherein the second gate structure comprises a second gate electrode and each second semiconductor channel material nanosheet has a second length that is less than the first length;
a middle dielectric isolation layer separating a bottommost second semiconductor channel material nanosheet of the spaced apart and vertically stacked second semiconductor channel material nanosheets from a topmost first semiconductor channel material nanosheet of the spaced apart and vertically stacked first semiconductor channel material nanosheets; and
a frontside gate cut structure located adjacent to the second forksheet transistor and located over the middle dielectric isolation layer, wherein the frontside gate cut structure electrically isolates the first gate electrode from the second gate electrode.

2. The semiconductor structure of claim 1, further comprising a dielectric wall structure contacting a sidewall of each first semiconductor channel material nanosheet, the middle dielectric isolation layer, and each second semiconductor channel material nanosheet.

3. The semiconductor structure of claim 2, further comprising a frontside contact structure passing through the frontside gate cut structure and the middle dielectric isolation layer and contacting the first gate electrode, wherein the frontside contact structure is spaced apart from the second gate electrode by a portion of the frontside gate cut structure.

4. The semiconductor structure of claim 3, further comprising a top gate middle-of-the-line (MOL) contact structure contacting the second gate electrode, and a bottom gate MOL contact structure contacting the frontside contact structure, wherein the top gate MOL contact structure and the bottom gate MOL contact structure are embedded in a MOL dielectric layer.

5. The semiconductor structure of claim 4, further comprising a frontside back-end-of-the-line (BEOL) interconnect structure contacting the MOL dielectric layer.

6. The semiconductor structure of claim 5, further comprising a backside gate cut structure located adjacent to the first gate electrode and contacting the frontside gate cut structure.

7. The semiconductor structure of claim 6, wherein the backside gate cut structure further contacts a backside interconnect structure.

8. The semiconductor structure of claim 2, further comprising a frontside contact structure passing through the frontside gate cut structure and the middle dielectric isolation layer and contacting the first gate electrode, wherein the frontside contact structure directly contacts a sidewall of the second gate electrode.

9. The semiconductor structure of claim 8, further comprising a top gate MOL contact structure contacting the second gate electrode, wherein the top gate MOL contact structure is embedded in a MOL dielectric layer.

10. The semiconductor structure of claim 9, further comprising a frontside BEOL interconnect structure contacting the MOL dielectric layer and the top gate MOL contact structure.

11. The semiconductor structure of claim 10, further comprising a backside gate cut structure located adjacent to the first gate electrode and contacting the frontside gate cut structure.

12. The semiconductor structure of claim 11, wherein the backside gate cut structure further contacts a backside interconnect structure.

13. The semiconductor structure of claim 2, further comprising a top gate MOL contact structure contacting the second gate electrode, and embedded in a MOL dielectric layer, and a backside contact structure contacting the first gate structure.

14. The semiconductor structure of claim 13, further comprising a frontside BEOL interconnect structure located on the MOL dielectric layer, and a backside interconnect structure contacting the backside contact structure.

15. The semiconductor structure of claim 14, further comprising a backside gate cut structure located adjacent to the first gate electrode and contacting the frontside gate cut structure and the backside interconnect structure.

16. The semiconductor structure of claim 2, further comprising a frontside bottom gate cut structure that passes through the frontside gate cut structure and the first gate electrode.

17. The semiconductor structure of claim 16, further comprising a frontside contact structure passing through the frontside gate cut structure and the middle dielectric isolation layer and contacting the first gate electrode, wherein the frontside contact structure is spaced apart from the second gate electrode by a portion of the frontside gate cut structure.

18. The semiconductor structure of claim 17, further comprising a MOL top gate contact structure contacting the second gate electrode and embedded in a MOL dielectric layer, and a MOL bottom gate contact structure contacting the frontside contact structure.

19. The semiconductor structure of claim 16, further comprising a frontside contact structure passing through the frontside gate cut structure and the middle dielectric isolation layer, and contacting the first gate electrode and a sidewall of the second gate electrode.

20. The semiconductor structure of claim 19, further comprising a MOL top gate contact structure contacting the second gate electrode, or a MOL bottom gate contact structure contacting the frontside contact structure.
